(19) United States
(12) Patent Application Publication
(10) Pub. No.: US 2014/0175483 A1
(43) Pub. Date: Jun. 26, 2014

(54) LIGHT EMITTING DIODE PACKAGE

(71) Applicant: ADVANCED OPTOELECTRONIC TECHNOLOGY, INC., Hsinchu Hsien (TW)

(72) Inventors: HOU-TE LIN, Hukou (TW); PIN-CHUAN CHEN, Hukou (TW); LUNG-HSIN CHEN, Hukou (TW)

(73) Assignee: ADVANCED OPTOELECTRONIC TECHNOLOGY, INC., Hsinchu Hsien (TW)

(21) Appl. No.: 14/014,374

(22) Filed: Aug. 30, 2013

(30) Foreign Application Priority Data
Dec. 22, 2012 (CN) 2012105618317

(51) Int. Cl. H01L 33/60

(52) U.S. Cl. CPC H01L 33/60
USPC 257/98

(57) ABSTRACT

An LED package includes a first electrode, a second electrode electrically insulated from the first electrode, a reflecting cup connecting the first electrode and the second electrode, and an LED chip. The first electrode includes an elongated first main portion and a first connecting portion bending downwardly from an end of the first main portion. The second electrode includes an elongated second main portion and a second connecting portion bending downwardly from an end of the second main portion. The LED chip is received in reflecting cup. The first main portion and the second main portion are embedded into the receiving cup, the end of the first main portion and the end of the second main portion extend outside the reflecting cup, and the first connecting portion and the second connecting portion are located outside the receiving cup.

### BACKGROUND

1. Technical Field

The present disclosure relates to semiconductor devices and, more particularly, to a light emitting diode (LED) package.

2. Description of Related Art

Presently, LEDs are preferred for use in non-emissive display devices than CCFLs (cold cathode fluorescent lamp) due to their high brightness, long lifespan, and wide color range.

A conventional LED package includes a substrate, an LED chip mounted on a top surface of the substrate, two electrodes electrically connected the LED chip and a reflector mounted on the top surface of the substrate and enclosing the LED chip therein. Accordingly, in many instances, for emitting light laterally, an LED chip is arranged on a side of an LED package. However, compared with a typical top-view LED package, a position of the LED chip needs to be changed, which results in a redesigning of a circuit connection and a space arrangement inside the LED package.

Accordingly, it is desirable to provide an improved LED package which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, top-side view of an LED package of a first embodiment of the present disclosure.

FIG. 2 is a cross sectional view of the LED package of FIG. 1, taken along a line II-II thereof.

FIG. 3 is a bottom-side view of the LED package of FIG. 1.

FIG. 4 is a schematic, top-side view of a first electrode and a second electrode of the LED package of FIG. 1.

FIG. 5 is a cross sectional view of the first electrode and the second electrode of FIG. 4, taken along a line V-V thereof.

FIG. 6 is a bottom-side view of the first electrode and the second electrode of FIG. 4.

### DETAILED DESCRIPTION

Embodiments of an LED package will now be described in detail below and with reference to the drawings.

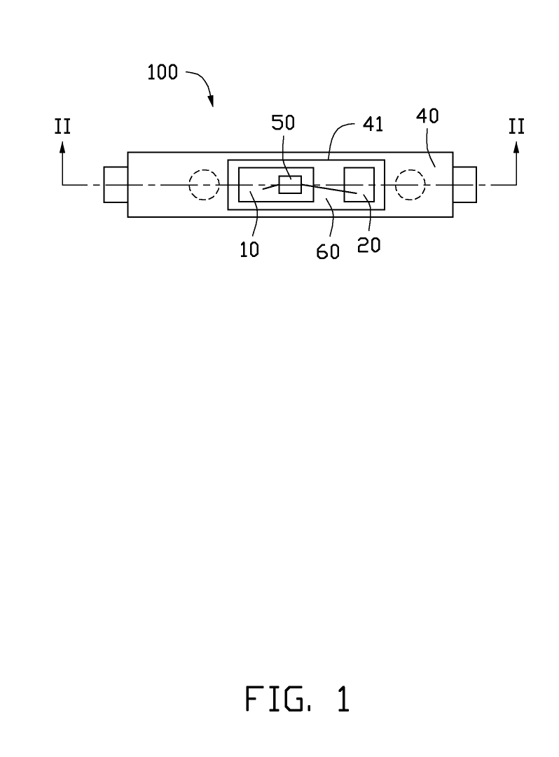

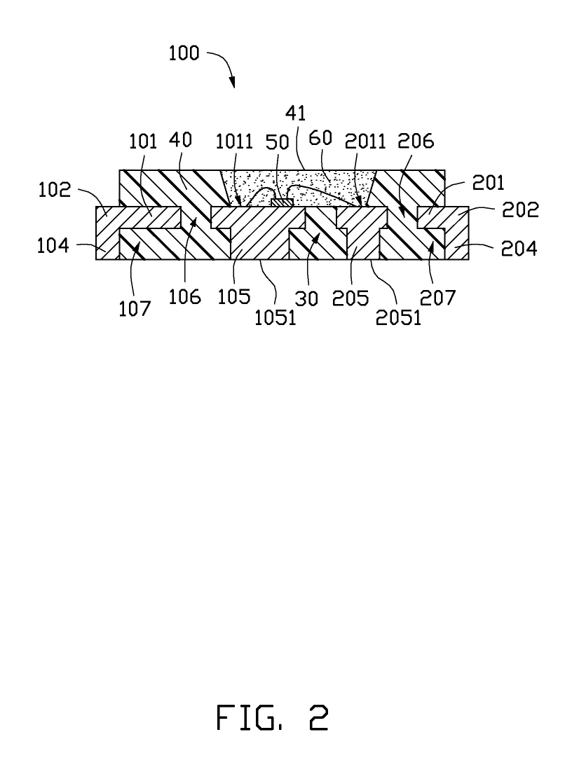

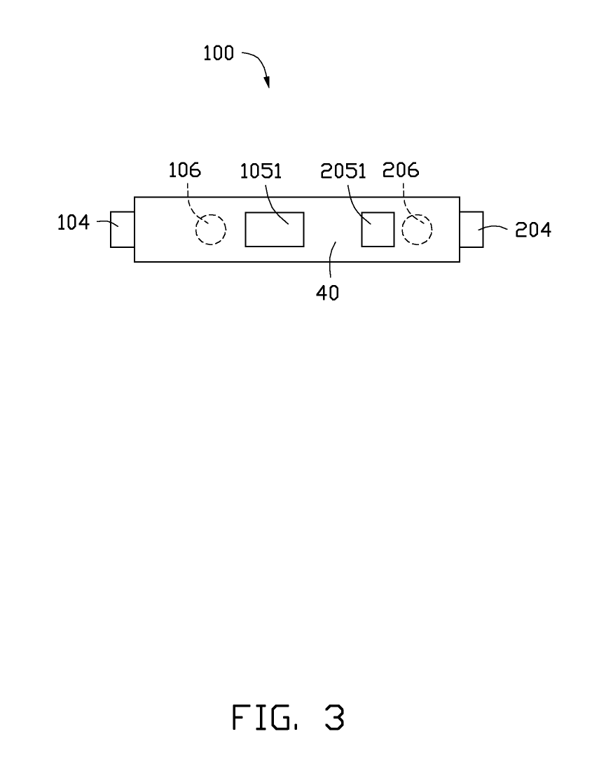

Referring to FIGS. 1-3, an LED package 100 according to an exemplary embodiment is shown. The LED package 100 includes a first electrode 10, a second electrode 20 spaced from the first electrode 10, a reflecting cup 40 having a receiving groove 41 and connecting the first electrode 10 and the second electrode 20, an LED chip 50 received in the receiving groove 41 of the reflecting cup 40 and electrically connecting the first electrode 10 and the second electrode 20, and an encapsulation layer 60 filled into the receiving groove 41 of the reflecting cup 40 and covering the LED chip 50.

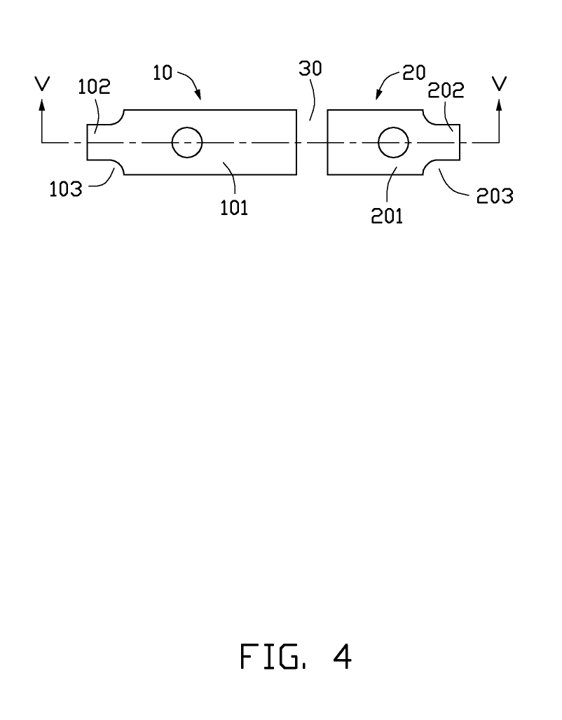

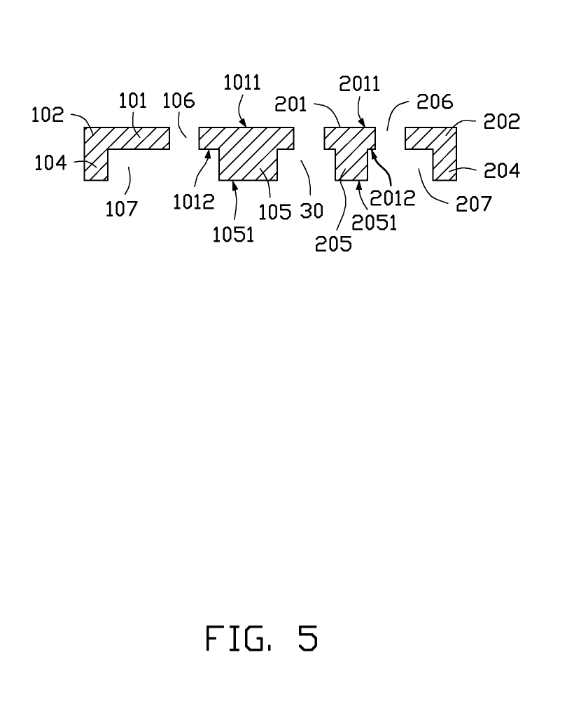

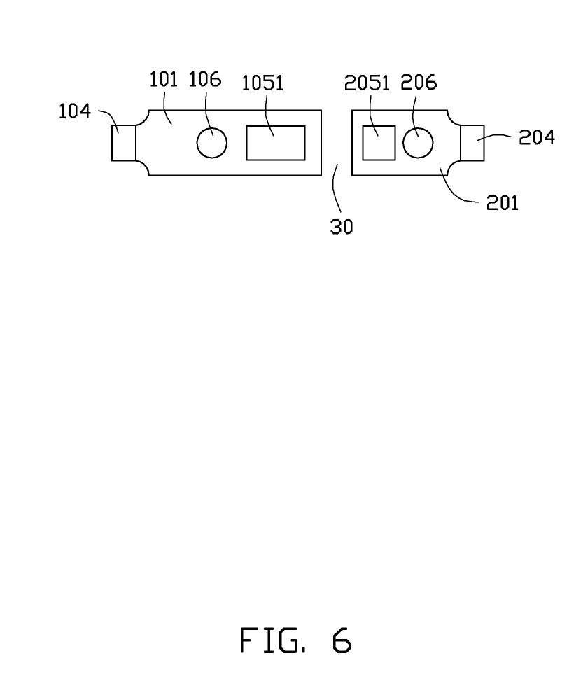

Referring to FIGS. 4-6 also, the first electrode 10 includes an elongated first main portion 101 and a first connecting portion 104 bending downwardly from an end 102 of the first main portion 101. The second electrode 20 includes an elongated second main portion 201 and a second connecting portion 204 bending downwardly from an end 202 of the second main portion 201. In this embodiment, the first electrode 10 and the second electrode 20 are made of copper or chromium. A top face of the first electrode 10 is coplanar with a top face of the second electrode 20. A bottom face of the first electrode 10 is coplanar with a bottom face of the second electrode 20. The first connecting portion 104 is perpendicular to the first main portion 101 of the first electrode 10. The second connecting portion 204 is perpendicular to the second main portion 201 of the second electrode 20. The first main portion 101 of the first electrode 10 is aligned with the second main portion 201 of the second electrode 20. The end 102 of the first main portion 101 is far away from the end 202 of the second main portion 201.

Two opposite lateral sides of the end 102 of the first main portion 101 are recessed inwardly to form two first recessed portions 103, respectively. Two opposite lateral sides of the end 202 of the second main portion 101 are recessed inwardly to form two second recessed portions 203, respectively. A width of the end 102 of the first main portion 101 is less than that of the first main portion 101. A width of the end 202 of the second main portion 201 is less than that of the second main portion 201. In use, when the LED package 100 is weld on a PCB (not shown) via solder, excess solder could be received in the first recessed portions 103 and/or the second recessed portions 203.

The first main portion 101 of the first electrode 10 and the second main portion 201 of the second electrode 20 are embedded into the reflecting cup 40. The end 102 of the first electrode 10 and the end 202 of the second electrode 20 extend outside the reflecting cup 40 from two opposite ends of the reflecting cup 40. The first connecting portion 102 and the second connecting portion 202 are correspondingly located at the two opposite ends of the reflecting cup 40. The first connecting portion 102 and the second connecting portion 202 are both exposed outside the reflecting cup 40.

The first main portion 101 has a first top face 1011 and a first bottom face 1012 opposite to the first top face 1011. The second main portion 201 has a second top face 2011 and a second bottom face 2012 opposite to the second top face 2011. A first thought hole 106 is defined in the first main portion 101 of the first electrode 10. The first thought hole 106 extends through the first main portion 101 from the first top face 1011 to the first bottom face 1012. A second thought hole 206 is defined in the second main portion 201 of the second electrode 20. The second thought hole 206 extends through the second main portion 201 from the second top face 2011 to the second bottom face 2012.

The first electrode 10 further includes a first block 105 extending downwardly and perpendicularly from the first bottom face 1012 of the first main portion 101. The second electrode 20 further includes a second block 205 extending downwardly and perpendicularly from the second bottom face 2012 of the second main portion 201. A width of the first block 105 is less than that of the first main portion 101. A width of the second block 205 is less than that of the second main portion 201.

The first block 105 extends through the reflecting cup 40. A bottom surface 1051 of the first block 105 is exposed outside the reflecting cup 40. The second block 205 extends through the reflecting cup 40. A bottom surface 2051 of the second block 205 is exposed outside the reflecting cup 40. The bottom surface 1051 of the first block 105 is coplanar with the bottom surface 2051 of the second block 205. The first block 105 is located adjacent to the second block 205. A bottom surface of the first connecting portion 104 is coplanar with the bottom surface 1051 of the first block 105. A bottom surface of the second connecting portion 204 is coplanar with the bottom surface 2051 of the second block 205.

A gap 30 is defined between the first electrode 10 and the second electrode 20. A first interspace 107 is defined between the first connecting portion 104 and the first block 105. The first interspace 107 is communicated with the first through hole 106. A second interspace 207 is defined between the second connecting portion 204 and the second block 205. The second interspace 207 is communicated with the second through hole 206. The reflecting cup 40 is filled into the gap 30, the first through hole 106, the second through hole 206, the first interspace 107 and the second interspace 207, whereby the first electrode 10 and the second electrode 20 tightly and fitly engage with the reflecting cup 40.

The reflecting cup 40 is made of silicone, epoxy resin or PMMA (polymethyl methacrylate). The reflecting cup 40 is annular, and is manufactured by injection molding or insert molding. When the reflecting cup 40 is manufactured, a mold for receiving a molding material is provided. The mold has a profile which is the same as that of the reflecting cup 40. A reflecting film (not shown) is further provided to coat on an inner surface of the receiving groove 41 to improve light outputting efficiency of the LED chip 50. The reflecting film is a metal film with a uniform thickness. The receiving groove 41 is recessed inwardly from a center of a top of the reflecting cup 40 along a top-to-bottom direction of the reflecting cup 40. The second top face 2011 of the second main portion 201 and the first top face 1011 of the first main portion 101 are partially exposed in the receiving groove 41.

The LED chip 50 is received in the receiving groove 41 and electrically connects the first electrode 10 and the second electrode 20 by wires. The LED chip 50 is mounted on the first top face 1011 of the first main portion 101 of the first electrode 10. It could be understood that, the LED chip 50 can be directly fixed on the first electrode 10 or the second electrode 20 in a manner of Flip-Chip without wires.

The encapsulation layer 60 is made of transparent or translucent silicone, which fills the receiving groove 41. Thus, the encapsulation layer 60 encapsulates the LED chip 50 therein to protect the LED chip 50. To convert wavelength of light generated from the LED chip 50, a fluorescent material such as garnet, sulfides, phosphates, aluminates, oxynitrides, silicates, nitrides, arsenides or tellurides can be filled and scattered in the encapsulation layer 60.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED (light emitting diode) package, comprising:
a first electrode comprising an elongated first main portion and a first connecting portion bending downwardly from an end of the first main portion;
a second electrode electrically insulated from the first electrode, the second electrode comprising an elongated second main portion and a second connecting portion bending downwardly from an end of the second main portion;
a reflecting cup having a receiving groove and connecting the first electrode and the second electrode; and
an LED chip received in the receiving groove and electrically connecting the first electrode and the second electrode;
wherein the first main portion and the second main portion are embedded into the receiving cup, the end of the first main portion and the end of the second main portion extend outside the reflecting cup, and the first connecting portion and the second connecting portion are located outside the receiving cup.

2. The LED package of claim 1, wherein two opposite lateral sides of the end of the first main portion are recessed inwardly to form two first recessed portions, respectively.

3. The LED package of claim 1, wherein two opposite lateral sides of the end of the second main portion are recessed inwardly to form two second recessed portions, respectively.

4. The LED package of claim 1, wherein a width of the end of the first main portion is less than that of the first main portion.

5. The LED package of claim 1, wherein a width of the end of the second main portion is less than that of the second main portion.

6. The LED package of claim 1, wherein the first main portion has a first top face and a first bottom face opposite to the first top face, and the second main portion has a second top face and a second bottom face opposite to the second top face.

7. The LED package of claim 6, wherein the receiving groove is recessed inwardly from a center of a top of the reflecting cup, and the first top face of the first main portion and the second top face of the second main portion are partially exposed in the receiving groove.

8. The LED package of claim 6, wherein a first thought hole is defined in the first main portion of the first electrode, the first thought hole extends through the first main portion from the first top face to the first bottom face, and the reflecting cup is filled into the first thought hole.

9. The LED package of claim 6, wherein a second thought hole is defined in the second main portion of the second electrode, the second thought hole extends through the second main portion from the second top face to the second bottom face, an the reflecting cup is filled into the second thought hole.

10. The LED package of claim 6, wherein the first electrode further comprises a first block extending downwardly from the first bottom face of the first main portion, the first block extends through the reflecting cup, and a bottom surface of the first block is exposed outside the reflecting cup.

11. The LED package of claim 10, wherein a bottom surface of the first connecting portion is coplanar with the bottom surface of the first block.

12. he LED package of claim 10, wherein the second electrode further comprises a second block extending downwardly from the second bottom face of the second main portion, the second block extends through the reflecting cup, and a bottom surface of the second block is exposed outside the reflecting cup.

13. The LED package of claim 12, wherein a bottom surface of the second connecting portion is coplanar with the bottom surface of the second block.

14. The LED package of claim 12, wherein the first block is located adjacent to the second block.

15. The LED package of claim 1, wherein a gap is formed between the first electrode and the second electrode, and the reflecting cup is filled into the gap.

16. The LED package of claim 1, wherein the end of the first electrode and the end of the second electrode extend outwardly from two opposite ends of the reflecting cup, respectively.

17. The LED package of claim 1, wherein the first connecting portion of the first electrode and the second connecting portion of the second electrode are located at two opposite ends of the reflecting cup, respectively.

18. The LED package of claim 1, further comprising an encapsulation layer filled into the receiving groove of the reflecting cup and covering the LED chip.

19. An LED package, comprising:
a first electrode comprising an elongated first main portion;
a second electrode electrically insulated from the first electrode, the second electrode comprising an elongated second main portion;
a reflecting cup having a receiving groove and connecting the first electrode and the second electrode; and
an LED chip received in the receiving groove and electrically connecting the first electrode and the second electrode;
wherein the first main portion and the second main portion are embedded into the receiving cup, a first end of the first main portion and a second end of the second main portion extend outside the reflecting cup, a width of the first end of the first main portion is less than that of the first main portion, and a width of the second end of the second main portion is less than that of the second main portion.

20. The LED package of claim 19, wherein two opposite lateral sides of the end of the first main portion are recessed inwardly to form two first recessed portions, and two opposite lateral sides of the end of the second main portion are recessed inwardly to form two second recessed portions.
